(19) United States
(12) Patent Application Publication
(10) Pub. No.: US 2006/0097388 A1
(43) Pub. Date: May 11, 2006

(54) Electrical system, especially a microelectronic or microelectromechanical high frequency system

(76) Inventors: Klaus Breitschwerdt, Filderstadt (DE); Markus Ulm, Sersheim (DE); Andrea Urban, Stuttgart (DE); Mathias Reimann, Renthingen (DE)

Correspondence Address: KENYON & KENYON LLP, ONE BROADWAY, NEW YORK, NY, 10004, US

(21) Appl. No.: 10/520,218

(22) PCT Filed: Jun. 24, 2003
(86) PCT No.: PCT/DE03/02087

§ 371 Date: Aug. 16, 2005

(30) Foreign Application Priority Data
Jul. 2, 2002 (DE) 10229578.6

(51) Int. Cl. H01L 23/34

(52) U.S. Cl. 257/728

(57) ABSTRACT

An electrical component is proposed, in particular a high-frequency microelectronic or microelectromechanical component having a base element that is provided with a feedthrough, a first conductive structure extending on an upper side of the base element being connected by the feedthrough, continuously for high-frequency electromagnetic waves, to a second conductive structure extending on a lower side of the base element. The feedthrough has the form of a right prism or cylinder, and the first and/or the second conductive structure is embodied as a planar waveguide, in particular as a coplanar waveguide. Also proposed is a method for producing an electrical component having a feedthrough for high-frequency electromagnetic waves through a base element, an electrically conductive layer being applied on an upper side of the base element and an etching mask being applied on a lower side of the base element; a trench, having at least almost perpendicular sidewalls and penetrating through the base element, then being etched into the base element in a plasma etching step; an electrically conductive layer being applied on the lower side after the etching and after removal of the etching mask; and the trench lastly being filled or lined with an electrically conductive material.

### FIELD OF THE INVENTION

The present invention relates to an electrical component, in particular a high-frequency microelectronic or microelectromechanical component, as well as a method for manufacturing the same.

### BACKGROUND INFORMATION

German Published Patent Application No. 100 37 385 discloses a micromechanically fabricated high-frequency short-circuit switch that has a thin metal bridge which is extended between two ground leads of a coplanar waveguide. This high-frequency short-circuit switch is usable, for example, for adaptive cruise control (ACC) or short-range radar (SRR) applications in motor vehicles, and is operated at operating frequencies of typically 24 or 77 gigahertz.

Many other microstructured or microsystem-engineering components are known besides, for example for applications in silicon-based high-frequency technology. These are also referred to as MEMS (microelectromechanical structures or systems) or HF-MEMS (high-frequency microelectromechanical structures or systems) components.

With microstructured components and in particular high-frequency microstructured components, it is generally necessary to protect them from environmental influences such as moisture, air, dirt particles, or other external media or gases. A capsule is often used for this purpose. To ensure that the functionality of the microstructured component enclosed by the capsule is not (or not too greatly) impaired, it is necessary to introduce a conductive structure into the capsule. The first problem that arises in this context is that of ensuring the requisite gas-tightness or moisture-tightness. In the context of passage of the conductor structure from the external space of the capsule into its interior space, it is also necessary to ensure, especially in the case of a high-frequency component, that the conductor structure remains transparent or permeable to high-frequency electromagnetic waves, i.e. there must be no appreciable damping of or interference with the propagation of the electromagnetic waves on the conductor structure.

U.S. Pat. No. 6,207,903 describes a microstructured silicon substrate in the form of a membrane having a high electrical conductivity that has feedthroughs between coplanar waveguides that are guided on different sides of the silicon substrate. These feedthroughs are embodied in the form of truncated circular cones and have been etched into the substrate from different sides thereof and filled with a metal, resulting in a high-frequency feedthrough between the coplanar waveguides guided on the upper side and lower side. The document moreover describes the fact that pyramidal feedthroughs penetrating through the substrate are also known. The etching method used in U.S. Pat. No. 6,207,903 for producing the feedthroughs is a wet-chemical etching method that utilizes the anisotropy of the etching rate in silicon single crystals along different crystal directions, so that (111) crystal planes always form as the side walls of the pyramidal feedthroughs. The side walls are thus not vertical, but always form an angle of 54.75° with the substrate plane. This method is explained in further detail in U.S. Pat. No. 5,913,134 in connection with the construction of high-frequency components having coplanar waveguides.

U.S. Pat. No. 6,365,513 discloses an electrical component, in particular a microelectronic or microelectromechanical component, having a base element that is provided with at least one feedthrough that connects, continuously at least for high-frequency electromagnetic waves, a first conductive structure extending on or in a vicinity of an upper side of the base element to a second conductive structure extending on or in a vicinity of a lower side of the base element, the feedthrough being embodied in the form of a right prism or a right cylinder.

U.S. Pat. No. 4,348,253 discloses an electrical component, in particular a high-frequency microelectronic or microelectromechanical component, having a base element that is provided with at least one feedthrough. The feedthrough connects a first conductive structure extending on or in a vicinity of an upper side of the base element and a second conductive structure extending on or in a vicinity of a lower side of the base element, the feedthrough being embodied in the form of a right prism or a right cylinder.

U.S. Pat. No. 5,618,752 describes a wafer having a via, extending from one surface to the other, that is etched into the base element using a plasma etching process.

U.S. Pat. No. 6,225,651 discloses a method for producing an electrical component having a feedthrough for high-frequency electromagnetic waves through a base element, an electrically conductive layer being applied at least locally on an upper side of the base element and an etching mask being applied on a lower side of the base element; at least one connection, penetrating through the base element and having at least almost perpendicular sidewalls, being etched into the base element by the etching mask in a plasma etching step; an electrically conductive layer being applied at least locally on the lower side after etching and after a removal of the etching mask; and the connection being at least largely filled or lined with an electrically conductive material.

The analysis of conductive vias that are insulated by silicon dioxide from a silicon wafer and serve to connect strip-shaped transmission channels is described in J. P. Quine, “Characterization of Via Connections in Silicon Circuit Boards,” IEEE Transactions in Microwave Theory and Techniques, Vol. 36, No. 1, pp. 21-27, January 1988.

Lastly, PCT Published Patent Application No. 02/33782 discloses an apparatus for guiding electromagnetic waves from a waveguide to a transmission channel. The apparatus encompasses coupling means containing at least one dielectric layer that has an opening which is embodied as an electrically conductive via.

The feedthroughs for high-frequency microelectronic or microelectromechanical components known from the aforesaid publications have the disadvantage that they require a great deal of space because of the anisotropic wet etching of silicon using the (111) plane as the etching stop, and that the coplanar waveguides for high-frequency electromagnetic waves in the gigahertz region guided on the silicon substrates described therein must be provided with special electrical adaptation structures to allow them to be integrated into a corresponding high-frequency component. These adaptation structures additionally result in a degradation of the high-frequency properties of the electrical components due to undesirable losses, a decrease in bandwidth, and the need for special impedance adaptation.

The object of the present invention was to make available an electrical component, in particular a high-frequency microelectronic or microelectromechanical component, that on the one hand can be hermetically encapsulated and on the other hand does not entail the aforesaid disadvantages of feedthroughs known from the existing art in terms of their high-frequency properties.

### SUMMARY OF THE INVENTION

The electrical component according to the present invention and the method according to the present invention for manufacturing it have the advantage, as compared with the existing art, that the feedthroughs can be manufactured to be very much smaller than in the existing art; and that additional special adaptation structures for integration of those feedthroughs into a circuit having conductive structures for high-frequency electromagnetic waves, in particular in the range from 1 GHz to 80 GHz, can usually be dispensed with.

It is further advantageous that established technologies, such as those known e.g. from German Patent No. 42 41 045, can be used for the individual method steps when carrying out the method according to the present invention. In particular, feedthroughs or so-called “vias” having almost perpendicular and smooth sidewalls can be implemented by dry plasma etching, and are characterized by low electrical losses in particular for high-frequency electromagnetic waves, as well as very good capability for integration into a high-frequency circuit environment. Feedthroughs of this kind are furthermore usable in all lead types or conductive structures from the family of planar waveguides, i.e., for example, coplanar waveguides, microstrip conductors, or so-called “slot lines” such as those already described in Meinke and Gundlach, “Taschenbuch der Hochfrequenztechnik” [Handbook of high-frequency engineering], Vol. 2, Verlag Springer, 1992.

A farther advantage of the plasma etching technique used to produce the feedthrough is the fact that the feedthroughs can now be fabricated with a high aspect ratio, i.e. a high ratio of diameter to height, of typically 1:10 or more, and at the same time with almost any desired cross section when viewed in plan, i.e. for example round, square, rectangular, or oval.

Advantageous refinements of the invention are evident from the features recited in the dependent claims.

For example, it is advantageous in terms of the desired high-frequency properties if the feedthrough is filled or lined with a metal, for example gold, as an electrically conductive material.

The dimensions of the feedthrough, when viewed in plan, are preferably in the range of an area of 400 μm² to 40,000 μm², in particular 1,600 μm² to 10,000 μm², or a diameter of 20 μm to 200 μm, in particular 40 μm to 100 μm.

The base element, i.e. usually a high-resistance silicon wafer having a specific resistance of more than 100 Ω/cm, advantageously has, at least in the region of the feedthrough, a typical thickness of 100 μm to 650 μm, for example 200 μm.

Lastly, a central problem in terms of protecting packaged or encapsulated high-frequency components or micromechanical components or sensor elements from external influences or the irradiation of electromagnetic fields is that of leading conductive structures that are connected to the packaged electrical high-frequency component out from an interior space enclosed by a capsule, since such leadthroughs must be configured to be on the one hand hermetically sealed and on the other hand compatible with high frequencies. An electrical component encapsulated according to a refinement of the invention advantageously avoids the problem of leading the conductive structures through the capsule by way of a backside contact through the base element, so that there is available around the encapsulated component an open area that can be used as a bonding surface for the capsule.

### BRIEF DESCRIPTION OF THE DRAWINGS

FIG. 1 schematically shows a section through a portion of a component having a feedthrough.

FIG. 2 is a plan view of the upper side of FIG. 1.

FIG. 3 is a plan view of the lower side of FIG. 1.

FIG. 4 depicts, in section, two adjacent unfilled or unlined feedthroughs in a base element.

FIG. 5 schematically shows a test structure having two feedthroughs and a configuration otherwise largely analogous to that shown in FIGS. 1 and 3, for measuring the high-frequency properties of that structure.

FIG. 6 shows a comparison of a measurement of the reflection damping of a double via feedthrough according to FIG. 5 as a function of frequency, and a comparison with a simulation based on an equivalent circuit diagram according to FIG. 7.

FIG. 7 is an equivalent circuit diagram for the configuration shown in FIG. 5.

FIG. 8 shows a comparison of a measurement of the transmission damping of a double via feedthrough according to FIG. 5 compared with a simulation on the basis of the equivalent circuit diagram shown in FIG. 7.

FIG. 9 shows an exemplified embodiment as an alternative to FIGS. 1 and 3, with an offset feedthrough.

FIG. 10 shows a further exemplified embodiment as an alternative to FIGS. 1 through 3, with a capacitative coupling of the conductive structures.

FIG. 11 shows a test structure largely analogous to FIG. 5, for analysis of the high-frequency properties of a feedthrough with capacitative coupling according to FIG. 10.

FIG. 12 shows several simulations of the reflection damping of a double via feedthrough with capacitative coupling according to FIG. 11, as a function of frequency and capacitance.

FIG. 13 is an equivalent circuit diagram of a double via feedthrough according to FIG. 11.

FIG. 14 schematically shows, in section, an electrical component constructed similarly to FIGS. 1, 5, or 9 and having a capsule.

FIG. 15 shows a configuration for coplanar-conductor portions.

FIG. 16 shows a configuration for microstrip leads.

FIGS. 17 and 18 show HF vias extending through a substrate.

### DETAILED DESCRIPTION

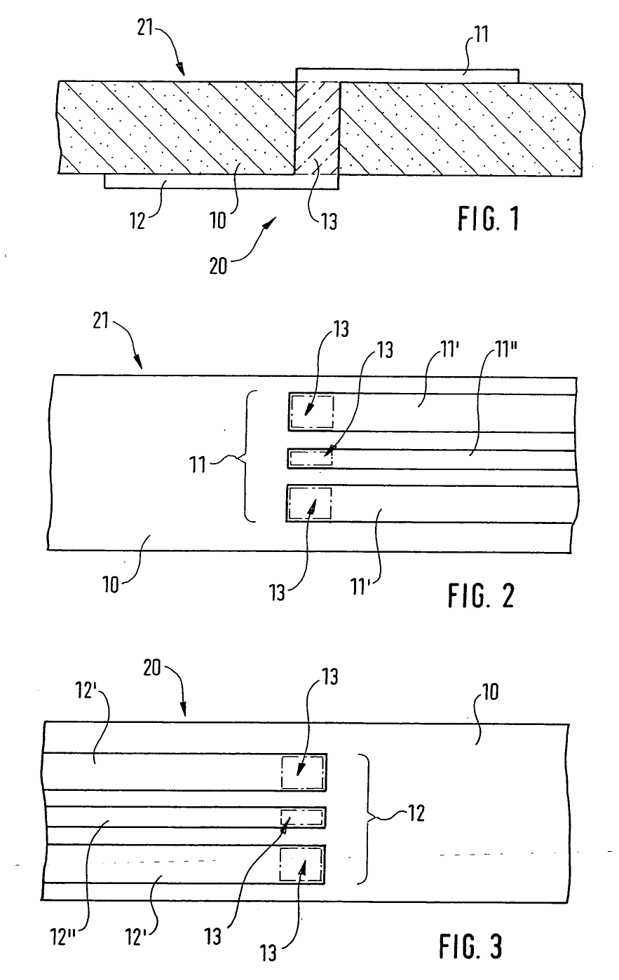

FIG. 1 explains a first exemplary embodiment for an electrical component 5 in the form of a high-frequency microelectronic component, a base element 10 in the form of a high-resistance silicon wafer having a specific electrical resistance of preferably more than 1000 Ω/cm being provided with a plurality of adjacent feedthroughs 13 or so-called “vias” that pass through base element 10 from its upper side 21 to its lower side 20. An upper conductive structure 11 is also provided on upper side 21, while a lower conductive structure 12 is located on lower side 20. Feedthroughs 13 are lined with a metal, for example gold, or another metal that can be deposited by electroplating. Lastly, provision is made for the lined feedthrough 13 to be connected in electrically conductive fashion to upper conductive structure 11 and to lower conductive structure 12, so that upper conductive structure 11 and lower conductive structure 12 are connected to one another continuously at least for high-frequency electromagnetic waves. Feedthrough 13 as shown in FIG. 1 has, viewed in three dimensions, the shape of a right prism or a right cylinder that is lined with the metal as a material having the best possible electrical conductivity.

FIG. 2 is a plan view of FIG. 1 showing that a total of three feedthroughs 13 are disposed on upper side 21 adjacently next to one another on a common connecting line. In FIG. 2, the dotted lines indicate feedthroughs 13, not actually visible in plan view, that are located below upper conductive structure 11. Upper conductive structure 11 as shown in FIG. 2 is embodied in the form of a coplanar waveguide as known from U.S. Pat. No. 6,207,903 B1 or DE 100 37 385 A1. In particular, upper conductive structure 11 has two ground leads 11′, extending parallel to one another, which enclose a signal lead 11″. As also shown in FIG. 2, ground leads 11′ and signal lead 11″ are connected from upper side 21 to lower side 20 of base element 10 by way of feedthroughs 13 conveyed respectively to them.

FIG. 3 is a plan view of lower side 20 according to FIG. 1 and the opposite side of FIG. 2. Here again, feedthroughs 13 that are not actually visible are indicated by dotted lines. Lastly, here again a planar waveguide in the form of a coplanar waveguide having two mutually parallel ground leads 12′ that enclose a signal lead 12″ extends, as lower conductive structure 12, on lower side 20 of base element 10.

FIG. 4 shows a section through a base element 10 with two feedthroughs 13 before they are filled or lined with an electrically conductive material, for example a metal. Particularly evident in FIG. 4 is the manner in which trenches 14 that extend perpendicular to base element 10 (which is flat at least in this region) and penetrate through it have been etched into substrate 10 (a silicon wafer, in the example explained) by anisotropic plasma etching using a dry plasma etching method, for example in accordance with DE 42 41 045 C1. It is clearly apparent that trenches 14 have almost perpendicular and largely smooth sidewalls, base element 10 according to FIG. 4 possessing a thickness of approx. 200 μm while the width of trenches 14 is approx. 100 μm.

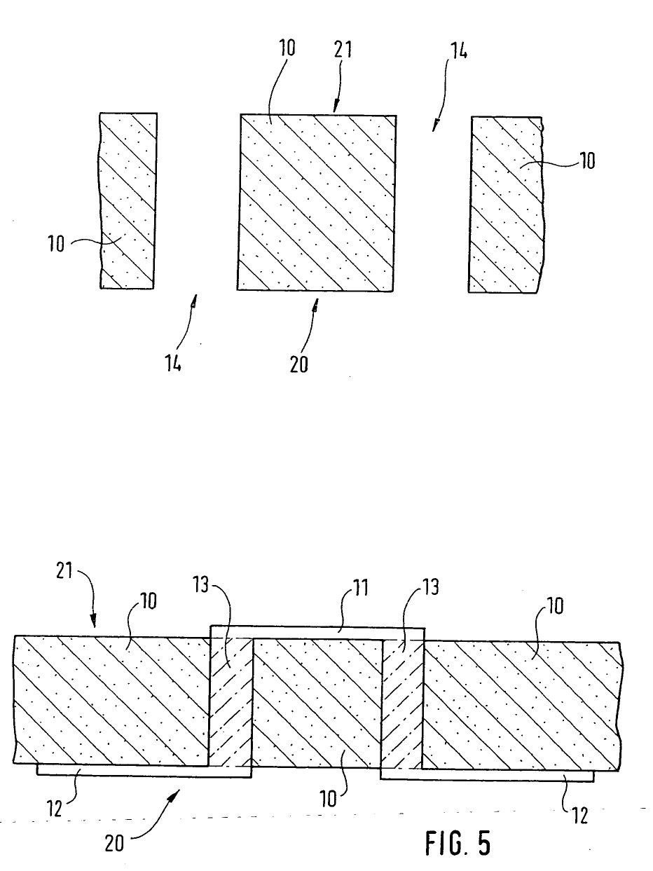

FIG. 5 shows a test structure for determining the high-frequency properties of an electrical component 5 having a feedthrough 13 from an upper conductive structure 11 to a lower conductive structure 12, as shown in FIG. 1 and in FIGS. 2 and 3. Unlike in FIG. 1, however, here two feedthroughs 13 are provided which are spaced apart from one another e.g. as shown in FIG. 4 and are filled or lined with a metal. These two feedthroughs 13 connect an upper conductive structure 11 disposed on upper side 21, in the form of a coplanar waveguide as shown in FIG. 2, to two lower conductive structures 12 that are likewise each embodied as coplanar waveguides in accordance with FIG. 3. Upper conductive structure 11 has, as shown in FIG. 5, a length I2 of 0.5 mm with an impedance of 46 Ω, while lower conductive structures 12 each have a length I1 of 2.35 mm and likewise an impedance of 46 Ω. Using the test structure shown in FIG. 5, a high-frequency alternating electromagnetic voltage is injected into the test structure in the region of a first measurement point 40, and the transmitted signal is received in the region of a second measurement point 41.

FIG. 7 is an equivalent circuit diagram for the test structure according to FIG. 5. This accounts for the fact that feedthroughs 13 can each be represented as series circuits of an ohmic resistance R with an inductance L that is connected in parallel with a capacitance Cₛ.

The higher-capacitance lining inside feedthroughs 13 is taken into account by capacitances Cₚ.

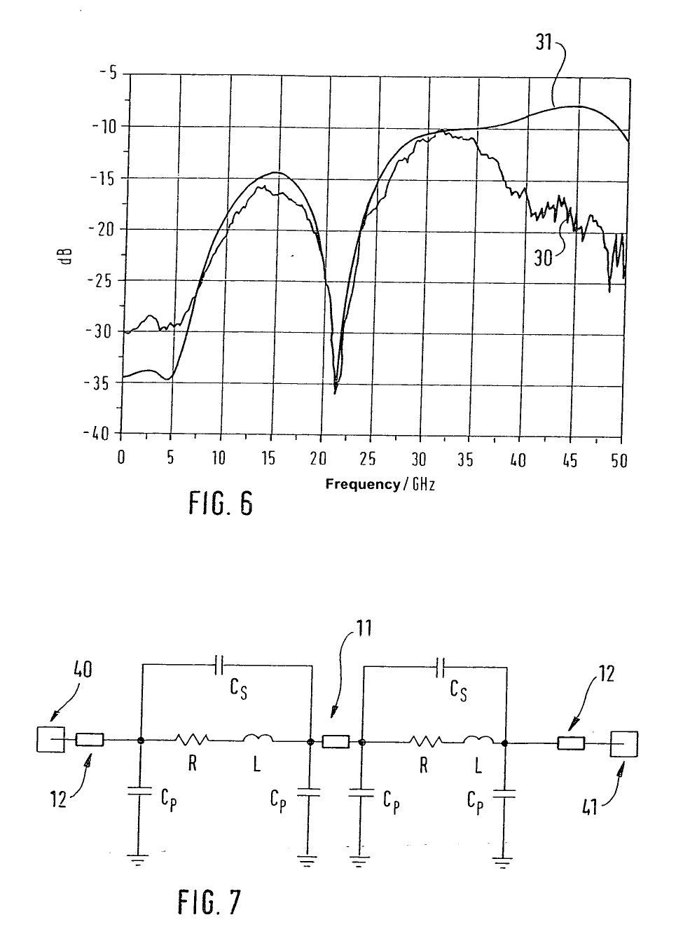

FIG. 6 shows a measurement 30 of the reflection damping of electromagnetic waves in the frequency range of approx. 1 GHz to approx. 50 GHz in the test structure shown in FIG. 5, as well as a comparison with a simulation 31 of the reflection damping in that frequency range, the equivalent circuit diagram of FIG. 7 with the indicated lengths I₁, I₂ and the indicated impedances of conductive structures 11, 12 having been employed for this simulation. It is evident that the simulation and measurement agree very well except for the frequency range greater than 35 GHz, so that a calculation, and thus also a controlled adjustment, of the properties of an electrical component 5 constructed similarly to FIG. 5 can be performed, in terms of reflection damping, using the equivalent circuit diagram of FIG. 7.

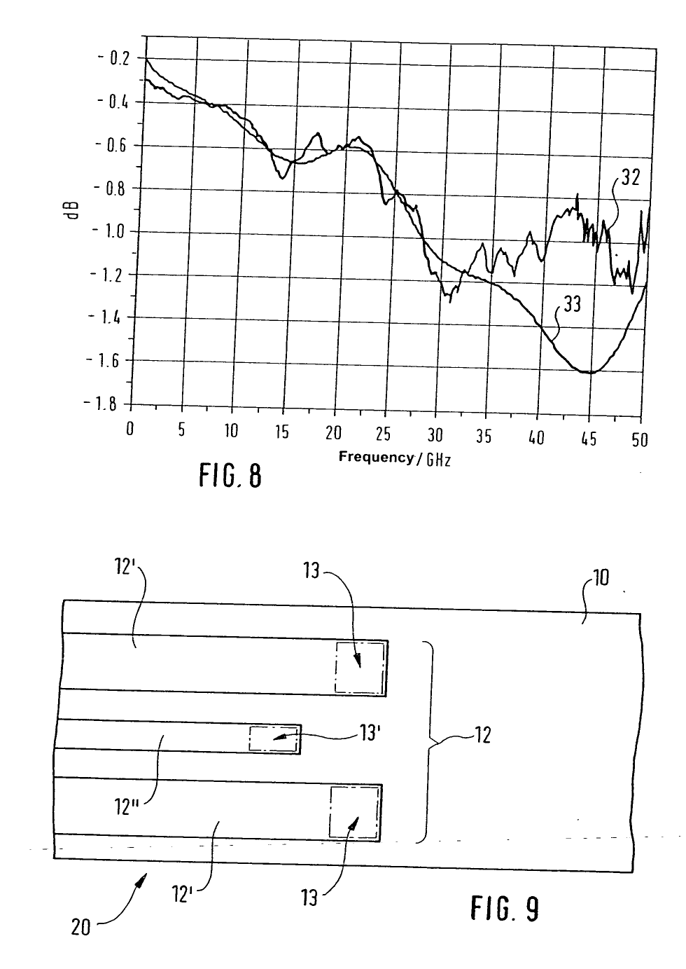

FIG. 8 shows a measurement 32 of the transmission damping on the test structure according to FIG. 5, as well as a comparison with simulation 33 of the transmission damping of test structure 5; here again, the equivalent circuit diagram of FIG. 7 was employed for simulation purposes. Measurement 32 of transmission damping once again agrees very well, except for the frequency range greater than 35 GHz, with simulation 33 of transmission damping.

FIG. 9 shows an exemplified embodiment that is slightly modified as compared with the exemplified embodiment according to FIGS. 1 through 3, feedthrough 13′ associated with upper signal lead 11″ and lower signal lead 12″ having been offset with respect to the two adjacent feedthroughs 13; in other words, FIG. 9 exhibits an offset feedthrough 13′ that is offset by a distance v of, for example, 50 μm to 300 μm, in particular 150 μm, with respect to the line connecting the two feedthroughs 13. The offset feedthrough 13′ can be set back with respect to the line connecting the two feedthroughs 13, as explained in FIG. 9, which is preferred; it can also, however, be offset forward. FIG. 9 furthermore shows only lower side 20 of base element 10, although it is clear that upper side 21 is configured correspondingly.

The offset feedthroughs 13, 13′ (so-called “staggered vias”) according to FIG. 9 result in a performance increase in terms of transmission properties for high-frequency electromagnetic waves. Simulation and measurement indicate especially low reflection and high transmission for electromagnetic waves in the GHz range at an offset v of 50 μm to 300 μm, in particular 150 μm.

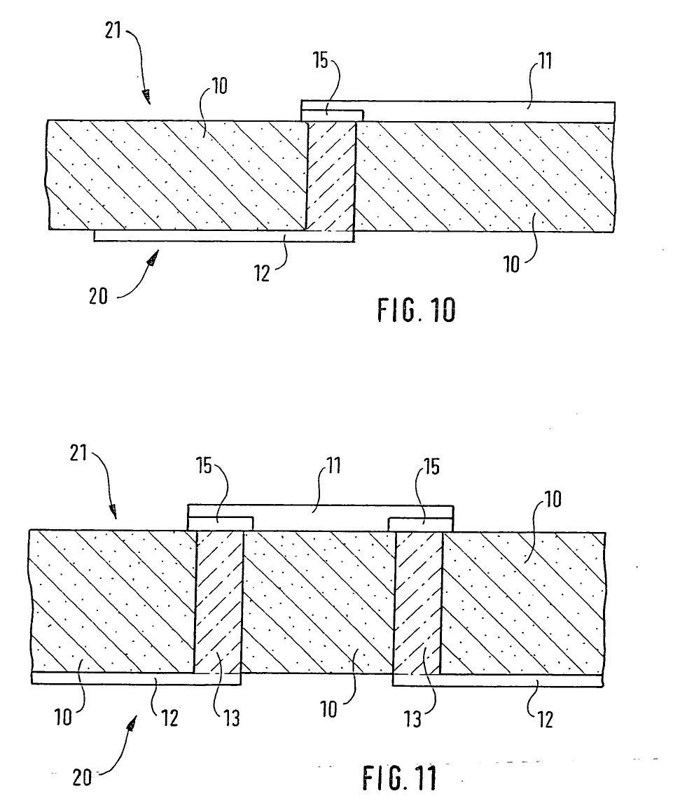

FIG. 10 shows a further exemplified embodiment as an alternative to the exemplified embodiment shown in FIG. 1 or 9; here, unlike in FIG. 1, upper conductive structure 11 is separated from feedthrough 13 by a dielectric 15, in particular in the form of a structured dielectric layer made e.g. of silicon dioxide. Upper conductive structure 11 is thereby electrically insulated from lower conductive structure 12 for direct current, while for high-frequency electromagnetic waves, dielectric 15 results in a capacitative coupling between upper conductive structure 11 and lower conductive structure 12 by way of feedthrough 13; in other words, the assemblage according to FIG. 10 acts similarly to a capacitor and can thus continue to transmit, in particular, very high-frequency electromagnetic waves in the GHz range.

If feedthrough 13 has a size of, for example, 50 μm×50 μm, dielectric 15 preferably has a thickness of 45 nm to 1800 nm, in particular 90 nm to 900 nm, which are values readily attainable in the context of ordinary technologies; this means that it constitutes, with conductive structures 11, 12 and feedthrough 13, a capacitor having a capacitance of 0.05 pF to 4 pF, in particular 0.1 pF to 2 pF. It is furthermore preferably dimensioned (in plan view) to correspond with the area of feedthrough 13 or to be slightly larger, and can additionally also be provided on lower side 20 or alternatively only on lower side 20 of base element 10. The variant shown in FIG. 10 is preferred.

FIG. 11 shows, proceeding from FIG. 10, a test structure for the analysis of transmission properties for high-frequency electromagnetic waves through a feedthrough with capacitative coupling according to FIG. 10, based on two parallel feedthroughs 13 that are acted upon by high-frequency electromagnetic waves in the region of a first measurement point 40. The high-frequency electromagnetic waves are then sensed in the region of a second measurement point 41 after transmission through the two feedthroughs and transmission via conductive structures 12, 11, 12. The dimensioning in FIG. 11 of upper conductive structure 11 and lower conductive structure 12, and of feedthroughs 13, corresponds (with the exception of dielectric 15) to the test structure shown in FIG. 5.

FIG. 13 shows an equivalent circuit diagram for the test structure according to FIG. 11 which differs from the equivalent circuit diagram of FIG. 7 for the test structure of FIG. 5 only in terms of the additional capacitance Cₛ, made available by dielectric 15, that is connected in series with ohmic resistance R and inductance L.

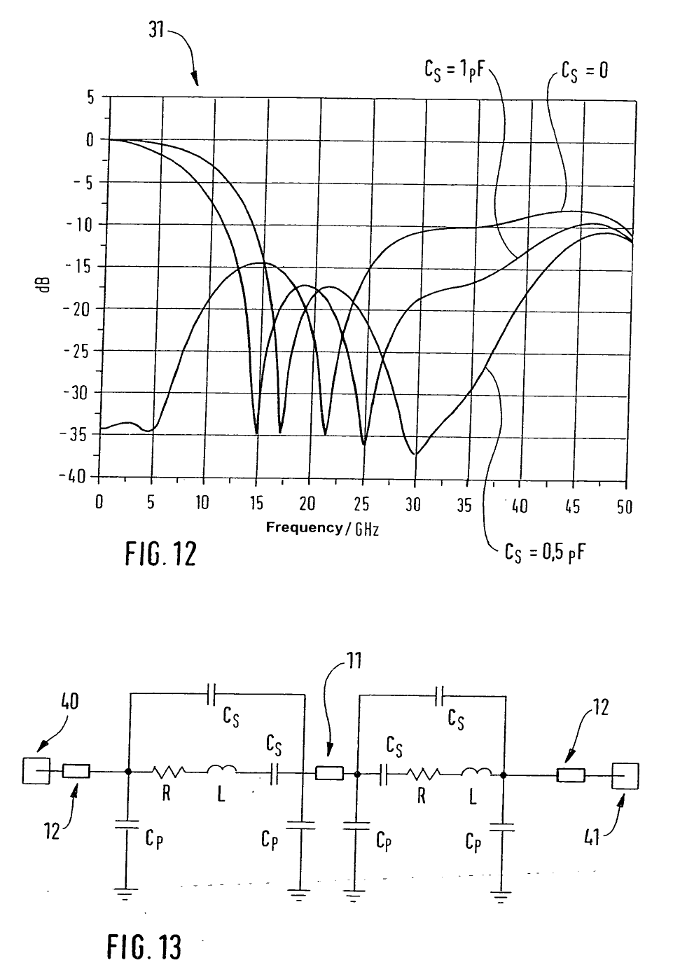

FIG. 12 shows several simulations 31 of the reflection damping for electromagnetic waves in the frequency range of approx. 1 GHz to approx. 50 GHz that were calculated using equivalent circuit 13 for test structure 11 as a function of capacitance Cₛ. For the case in which Cₛ=0, i.e. in which dielectric 15 is not present, the result is once again the test structure shown in FIG. 5 and the equivalent circuit according to FIG. 7. To that extent, simulation 31 of the reflection damping for Cₛ=0 in FIG. 12 is identical to the corresponding simulation 31 of the reflection damping in FIG. 6. It is further evident from FIG. 12 that the transmission properties of test structure 11 change considerably as a function of capacitance Cₛ, so that by varying capacitance Cₛ it is possible to adapt the transmission and reflection properties of test structure 11 for high-frequency electromagnetic waves to a desired properties profile in a manner that is controlled and can be calculated a priori.

The overall result of using a dielectric layer 15 as shown in FIG. 10 and FIG. 11 is that the transmission properties of the test structure and also those of an electrical component 5 can now be adapted in controlled fashion as a function of frequency. Changing capacitance Cₛ from 0.1 pF to 2 pF, for example, shifts the center frequency according to FIG. 12 from approx. 10 GHz to approx. 50 GHz.

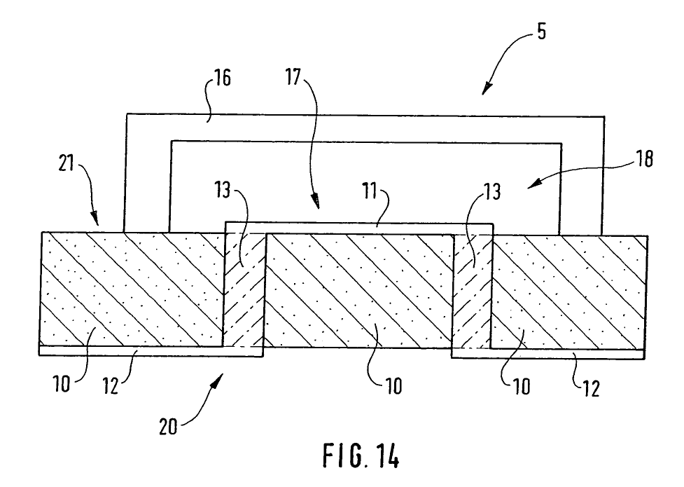

FIG. 14 is a schematic sketch of a complete electrical component 5, in particular a high-frequency microelectronic or microelectromechanical component, two feedthroughs 13 being provided that each connect lower side 20 of base element 10, which is a silicon wafer, to its upper side 21. Extending on lower side 20 are lower conductive structures 12, each associated with one of feedthroughs 13, that are embodied in the form of coplanar waveguides according to FIG. 3. Upper conductive structure 11 on upper side 21 is likewise embodied as a coplanar waveguide and is connected to an electrical component 17 or sensor element (not depicted in further detail), in particular a high-frequency microelectronic or microelectromechanical component. This electrical component 17 is, for example, a high-frequency diode, a high-frequency transistor, a micromechanically fabrioated short-circuit switch according to DE 100 37 385 A1, or another micromechanically fabricated sensor element.

Lastly, there is provided according to FIG. 14 a capsule 16 that encapsulates electrical component 17 in hermetically sealed fashion and thus protects it from environmental influences such as moisture, corrosion, dirt, and undesirable gases.

The material of capsule 16 is preferably a material that has a coefficient of thermal expansion similar to that of the material of base element 10, i.e. silicon, and that can also be manufactured using microsystems engineering. Silicon and a float glass such as borosilicate float glass are preferably used as the material for capsule 16.

For the manufacture of capsule 16, suitably dimensioned cavities, in which electrical component 17 embodied, for example, as a high-frequency microelectromechanical component (“HF MEMS structure”) is later located, are etched in the usual fashion into a silicon disk or glass disk.

A glass frit is preferably used to mount capsule 16 on base element 10, in particular using a “bonding frame.” In the case of borosilicate float glass, anodic bonding can also be utilized. The encapsulated components are then diced by sawing 17, and integrated into a circuit environment. In addition, if necessary, the encapsulated electrical components 17 can also be provided on the integration side, after metallization of feedthroughs 13, with usual connection contacts (“bumps”) for a soldering or adhesive bonding process.

Capsule 16 thus creates a hermetically sealed interior space 18 in which electrical component 17—which is connected, continuously for high-frequency electromagnetic waves, via upper conductive structure 11 and feedthroughs 13 to lower conductive structures 12 and can be electrically activated thereby—is located on base element 10 or in the region of the surface of base element 10.

In all the aforementioned exemplified embodiments, feedthroughs 13 are constituted by trenches 14, etched into substrate 10 using a plasma etching method, that have been filled or lined with, for example, a metal. Feedthroughs 13 are thus embodied as filled or lined right prisms, i.e. solids having congruent polygons as their base outlines, the edges being perpendicular to the base outline; or as filled or lined right cylinders, i.e. solids delimited by a cylindrical surface having a closed directrix and two parallel planes (the base outlines of the cylinder). Feedthroughs 13 are, in particular, relatively small as compared with the existing art, and they have a relatively high aspect ratio with a largely arbitrary cross section. It should furthermore be emphasized that what primarily governs the high-frequency properties of feedthroughs 13 is not the thickness of base element 10 but rather their lateral dimensions and their shape.

The high-frequency feedthroughs (HF vias) according to the present invention can be utilized, for example, at crossover points, thereby allowing the construction of low-loss high-frequency crossovers.

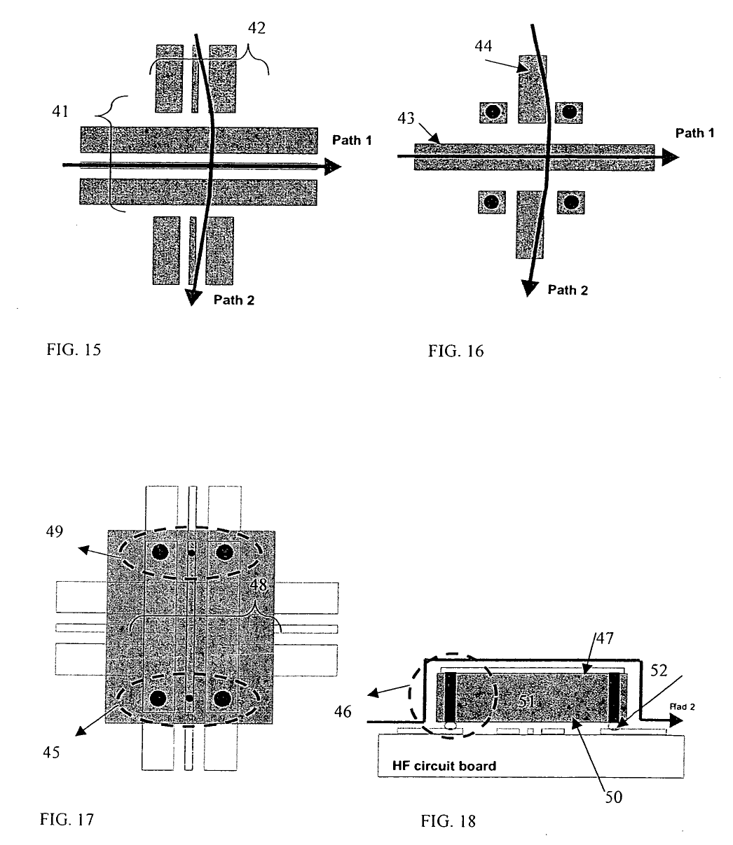

In a crossover, one signal path is continued and the other is interrupted. FIG. 15 shows such a configuration for coplanar conductor paths (41, 42), and FIG. 16 one for microstrip leads (43, 44). This interruption is bridged, according to the present invention, using the following structure. A coplanar HF via (45, 46) leads from the lower side (50) to the upper side (47) of the substrate (51), e.g. silicon (see FIGS. 17 and 18). There a coplanar lead (48) runs on the other side of the structure, where it adjoins a further HF via (49) that in turn leads to the lower side (50) of the substrate (51). The lower signal path is therefore bridged, but may possibly require an impedance adaptation because of the influence of the substrate. The chip (substrate) (51) can be provided with bumps (52), thus creating the electrical and mechanical contact.

The method for manufacturing a feedthrough 13 as shown in FIG. 1 provides that firstly, purified high-resistance silicon having a specific resistance of more than 1000 Ω/cm is made available as the starting material or base element 10; onto one side, e.g. upper side 21, of this a conductive, electroplating-compatible metal layer is sputtered and then patterned as applicable; a photoresist is then applied onto lower side 20 of base element 10 and is photolithographically patterned in the region of feedthroughs 13 that are to be produced, i.e. a resist mask is formed as an etching mask; then, in a dry plasma etching step e.g. in accordance with DE 42 41 045 C1, the silicon is etched through base element 10 to the oppositely located metal layer in the region of feedthroughs 13 that are to be produced; after subsequent removal of the resist mask, the side of base element 10 not initially metallized is likewise at least locally metallized by sputtering; then, by application of a resist mask onto both sides of base element 10 and subsequent electroplating reinforcement, conductive structures 11, 12 are produced in the form of, for example, coplanar waveguides for high-frequency electromagnetic waves, and at the same time the previously produced feedthroughs 13 are reinforced with metal; and lastly the usual electroplated supply leads produced on both sides for purposes of electroplating reinforcement are removed again by way of an etching step, so that what remains in addition to conductive structures 11, 12 are feedthroughs 13 that have been produced and lined with a metal.

An alternative variant of this method provides that after the purified high-resistance silicon is made available as the starting material, firstly a dielectric layer is applied on one side onto upper side 21 and optionally patterned; then the conductive, electroplating-compatible metal layer is sputtered onto one side and optionally patterned; then a photoresist is again applied onto lower side 20 and photolithographically patterned in the region of feedthroughs 13 that are to be produced, resulting in a resist mask constituting an etching mask; and the silicon is then etched through in a plasma etching step, in the region of feedthroughs 13 that are to be produced, to the dielectric layer present on the opposite side, forming trenches 14 that penetrate perpendicularly through base element 10. After removal of the resist mask constituting the etching mask, the dielectric layer (which preferably is an oxide layer) is then firstly removed again at least in the region of feedthroughs 13 that are to be produced, and the side of base element that was initially not metallized is metallized, for example by sputtering, before conductive structures 11 and 12 are once again produced by the application of photoresist masks onto both sides of base element 10 and subsequent electroplating reinforcement, and feedthrough 13 is reinforced with metal or lined with a metal. Lastly, electroplating supply leads produced on either side of base element 10 are removed again in an etching step, so that only conductive structures 11, 12 and feedthrough 13 remain.

It should additionally be emphasized-that the methods explained above are suitable for the realization of all known types of conductive structures, in particular planar waveguides such as coplanar waveguides, microstrip leads, and so-called “slot lines.”

The method for producing an electrical component 5 according to FIG. 10 having at capacitative coupling by way of a dielectric 15 differs from the method explained above only in that after removal of the etching mask after the plasma etching step, dielectric 15, which once again is preferably present as an oxide layer, is not removed again in the region of feedthrough 13, and the not-yet-metallized side of base element 10 is metallized in the presence of dielectric 15, for example by sputtering. The remainder of the procedure is then as already described above.

Alternatively or in addition to the use of a dielectric layer 15 for capacitative coupling, further series capacitances can also be used in the region of upper conductive structure 11 and/or in the region of lower conductive structure 12 for HF compensation, these being implemented e.g. by way of capacitative lead segments, for example interdigital capacitances, upstream from conductive structures 11, 12.

1-21. (canceled)

22. An electrical component, comprising:
a first conductive structure;
a second conductive structure;
at least one feedthrough including one of a right prism and a right cylinder;
a base element provided with at least one feedthrough that connects, continuously at least for high-frequency electromagnetic waves, the first conductive structure, the first conductive structure extending on or in a vicinity of an upper side of the base element, to the second conductive structure, the second conductive structure extending on or in a vicinity of a lower side of the base element, wherein each one of the first conductive structure and the second conductive structure includes a planar waveguide.

23. The electrical component as recited in claim 22, wherein the electrical component is one of a high-frequency microelectronic component and a microelectromechanical component.

24. The electrical component as recited in claim 22, wherein each one of the first conductive structure and the second conductive structure includes a coplanar waveguide

25. The electrical component as recited in claim 22, wherein the at least one feedthrough is one of filled and lined with an electrically conductive material corresponding to a metal.

26. The electrical component as recited in claim 22, wherein:
the base element is flat at least in a vicinity of the at least one feedthrough, and
the at least one feedthrough extends perpendicularly to a plane spanned by the vicinity of the base element that is flat and penetrates through the base element.

27. The electrical component as recited in claim 22, wherein the at least one feedthrough is etched into the base element using a plasma etching method and then one of filled and lined with an electrically conductive material.

28. The electrical component as recited in claim 22, wherein the at least one feedthrough is one of round, oval, square, and rectangular in plan view.

29. The electrical component as recited in claim 22, wherein at least one of:
the at least one feedthrough occupies in plan view an area of 400 μm² to 40,000 μm², and
the at least one feedthrough has a diameter of 20 μm to 200 μm, in particular 40 μm to 100 μm.

30. The electrical component as recited in claim 29, wherein:
the at least one feedthrough occupies in plan view an area of 1,600 μm² to 10,000 μm², and
the at least one feedthrough has a diameter of 40 μm to 100 μm.

31. The electrical component as recited in claim 22, wherein the base element has, in a region of the at least one feedthrough, a thickness of 100 μm to 650 μm.

32. The electrical component as recited in claim 22, wherein the base element includes a high-resistance silicon disk having a specific electrical resistance of more than 1000 Ω/cm

33. The electrical component as recited in claim 22, further comprising:
a dielectric by which the first conductive structure and the second conductive structure are separated.

34. The electrical component as recited in claim 22, wherein:
the dielectric includes a patterned dielectric layer.

35. The electrical component as recited in claim 33, wherein:
the dielectric, the first conductive structure, the second conductive structure, and the at least one feedthrough form a capacitor having a capacitance of 0.05 pF to 4 pF.

36. The electrical component as recited in claim 35, wherein:
the capacitance is 0.1 pF to 2 pF.

37. The electrical component as recited in claim 33, wherein:
the dielectric includes a silicon oxide layer having a thickness of 45 nm to 1800 nm.

38. The electrical component as recited in claim 37, wherein:
the dielectric includes a silicon oxide layer having a thickness of 90 nm to 900 nm.

39. The electrical component as recited in claim 22, wherein:
the at least one feedthrough includes a first feedthrough, a second feedthrough, and a third feedthrough,
the first conductive structure includes an upper coplanar waveguide having:
a first upper ground lead,
an upper signal lead, and
a second upper ground lead, the first upper ground lead, the upper signal lead, and the second upper ground lead extending at least locally parallel to one another,
the second conductive structure includes a lower coplanar waveguide having:
a first lower ground lead,
a lower signal lead, and
a second lower ground lead, the first lower ground lead, the lower signal lead, and the second lower ground lead extending at least locally parallel to one another,
the first upper ground lead is connected to the first lower ground lead by way of the first feedthrough,
the second upper ground lead is connected to the second lower ground lead by way of the second feedthrough,
the upper signal lead is connected to the lower signal lead by way of the third feedthrough, and
the third feedthrough is offset with respect to the first feedthrough and the second feedthrough.

40. The electrical component as recited in claim 39, wherein in plan view, the offset of the third feedthrough on the base element is 50 μm to 300 μm.

41. The electrical component as recited in claim 39, wherein in plan view, the offset of the third feedthrough on the base element is 150 μm.

42. The electrical component as recited in claim 22, wherein one of the first conductive structure and the second conductive structure locally has a capacitative component, corresponding to an interdigital capacitor, for further HF compensation.

43. The electrical component as recited in claim 22, further comprising:
one of an electrical component and a sensor element provided on an upper side of the base element and capable of being electrically activated by way of the at least one feedthrough from the lower side of the base element.

44. The electrical component as recited in claim 43, wherein:
the at least one feedthrough includes at least two feedthroughs,
the one of the electrical component and the sensor element is capable of being activated by way of the at least two feedthroughs, and
the at least one of the electrical component and the sensor element includes a high-frequency microelectronic or a microelectromechanical component such as a high-frequency diode or a high-frequency transistor, a micromechanically fabricated short-circuit switch for high-frequency electromagnetic waves, or a micromechanically fabricated sensor element.

45. The electrical component as recited in claim 22, wherein the electrical component is provided, on the upper side of the base element, with a hermetically sealed capsule.

46. A method for producing an electrical component including a feedthrough for high-frequency electromagnetic waves through a base element, the method comprising:
applying an electrically conductive layer at least locally on an upper side of the base element;
applying an etching mask on a lower side of the base element;
etching at least one trench, having at least almost perpendicular sidewalls and penetrating through the base element, into the base element by the etching mask in a plasma etching step;
applying the electrically conductive layer at least locally on the lower side after the etching and after removal of the etching mask; and
one of at least largely filling and at least largely lining the at least one trench with an electrically conductive material by electroplating deposition.

47. The method as recited in claim 46, wherein the electrically conductive layer is produced by one of deposition and sputtering of a metal suitable for subsequent electroplating reinforcement, and is patterned in accordance with a conductive structure) to be produced on at least one of the upper side and the lower side.

48. The method as recited in claim 47, further comprising:
applying a photoresist that is photolithographically patterned as the etching mask.

49. The method as recited in claim 46, wherein after the at least one trench is etched in, photoresist masks are applied on both sides of the base element, and metal conductive structures in the form of planar waveguides are deposited by electroplating on the upper side and the lower side together with the electrically conductive material.

50. The method as recited in claim 46, further comprising:
locally depositing a dielectric layer, adapted in plan view to an area of the feedthrough to be produced or slightly larger, on the upper side of the base element prior to deposition there of the electrically conductive layer.

51. The electrical component as recited in claim 22, wherein the electrical component is sued to create low-loss high-frequency crossovers.
